(19) United States
(12) Patent Application Publication
(10) Pub. No.: US 2013/0221983 A1
(43) Pub. Date: Aug. 29, 2013

(54) SYSTEMS AND METHODS FOR PROVIDING TRANSFORMER RATINGS USING HARMONICS DATA

(71) Applicant: GridSense, Inc., (US)

(72) Inventor: Kevin Joseph Anderson, Eik Grove, CA (US)

(73) Assignee: GridSense, Inc., West Sacramento, CA (US)

(21) Appl. No.: 13/771,270

(22) Filed: Feb. 20, 2013

Related U.S. Application Data
(60) Provisional application No. 61/604,173, filed on Feb. 28, 2012.

(51) Int. Cl. G01R 31/02

(52) U.S. Cl. CPC G01R 31/027
USPC 324/547

(57) ABSTRACT

A method of providing transformer rating information. The method includes the steps of: (a) determining k-factors for eddy losses and stray losses related to a transformer; and (b) providing a revised rating for the transformer using the k-factors determined at step (a).

### RELATED APPLICATION

This application claims the benefit of priority to U.S. Provisional Patent Application Ser. No. 61/604,173, filed on Feb. 28, 2012, the contents of which are incorporated in this application by reference.

### TECHNICAL FIELD

This invention relates generally to the field of transformer monitoring and, more particularly, to improved systems and methods for providing transformer ratings using harmonics data.

### BACKGROUND OF THE INVENTION

With the increasing use of non-linear loads on power circuits, harmonic distortion (e.g., voltage and current frequencies riding on top of a normal sinusoidal voltage and current waveform) is also increasing. This harmonic distortion has many effects including the potential overheating of power transformers, and the corresponding loss of life of such power transformers.

The effects of harmonic distortion on the life expectancy (and operation limitations) of a transformer are related to the construction of the transformer, as well as tested parameters unique to each transformer. The as-tested parameter data are not available for many units after manufacturing, particularly the millions of small distribution transformers (e.g., pole-mounted transformers, residential distribution transformers, etc.) presently installed.

Thus, a need exists for, and it would be desirable to provide, improved systems and methods for determining the impact of harmonics on transformers (e.g., transformers for which certain manufacturing information does not exist), and for providing revised transformer ratings related to the harmonics.

### BRIEF SUMMARY OF THE INVENTION

To meet this and other needs, and in view of its purposes, the present invention provides, according to an exemplary embodiment, a method of providing transformer rating information. The method includes the steps of: (a) determining k-factors for eddy losses and stray losses related to a transformer; and (b) providing a revised rating for the transformer using the k-factors determined at step (a).

According to another exemplary embodiment of the present invention, another method of providing transformer rating information is provided. The method includes the steps of: (a) determining k-factors for eddy losses and stray losses related to a transformer for a time period; (b) providing a revised rating for the transformer for the time period using the k-factors determined at step (a); and (c) repeating steps (a) and (b) for a plurality of additional time periods.

According to another exemplary embodiment of the present invention, a system of providing transformer rating information is provided. The system includes monitoring equipment for obtaining data related to a transformer, and a computer for providing a revised rating for the transformer using k-factors for eddy losses and stray losses related to the transformer.

It is to be understood that both the foregoing general description and the following detailed description are exemplary, but are not restrictive, of the invention.

### BRIEF DESCRIPTION OF THE DRAWINGS

The invention is best understood from the following detailed description when read in connection with the accompanying drawings. It is emphasized that, according to common practice, the various features of the drawings are not to scale. On the contrary, the dimensions of the various features are arbitrarily expanded or reduced for clarity. Included in the drawing are the following figures:

FIGS. 1-4 are flow diagrams illustrating methods of providing transformer rating information in accordance with various exemplary embodiments of the present invention; and

FIG. 5 is a block diagram of a pole-mounted distribution transformer and monitoring equipment for obtaining information related to the transformer in accordance with an exemplary embodiment of the present invention.

### DETAILED DESCRIPTION OF THE INVENTION

It is presently recognized by industry standards (e.g., IEC, IEEE, ANSI) that utility power transformers are harmfully affected by harmonic loads, that is, electrical currents with harmonic content. It is also known that transformers are capable of a reduced load capacity when the operating temperature increases due to these loads. There is no industry standard, however, for making such a calculation.

According to certain exemplary embodiments of the present invention, a method is provided including steps of: (1) measuring harmonic content going through the transformer (e.g., through a determination of k-factors); (2) combining the measured harmonic content with a measure of transformer losses to refine a measure of the expected effects of a harmonic load; and (3) calculating a degree of increased heat generated by the transformer. As will be understood by those skilled in the art, a determination may be made as to the effect of the increased heat at full load, and a determination of a reduced rated power of the transformer. The reduced rated power may desirably accommodate the harmonic content and maintain a rated temperature rise, therefore maintaining a rated loss of insulation life.

In one variation, the measurement of transformer losses (e.g., by use of metering or by measure of heat dissipation) may be omitted. In such a case, a manual input of the distribution of transformer losses (e.g., stray, eddy, and resistive losses) may be provided to calculate the present losses including the effects of harmonics.

An exemplary feature of the present invention is the dynamic (or substantially dynamic) measurement of the losses of a transformer that has known harmonic loads, and a modification to a distribution of such transformer losses (e.g., resistive, stray, and eddy percentages of the total losses). Another exemplary feature of the present invention is the dynamic (or substantially dynamic) calculation of a de-rating (e.g., a reduced power/load rating) of the transformer based on the harmonic load, for example, in order to maintain an allowable temperature rise, or ultimate temperature of the transformer.

By implementing systems and methods according to the present invention, transformer users/owners (e.g., electrical utility companies) may more accurately calculate the impact of harmonic load content on the transformer lifespan. Transformers may have their load dynamically limited to maintain a limit of the loss-of-life rate. Utilities may more intelligently use demand-side management programs to lessen loads on transformers with more harmonic content before other transformers, accomplishing the overall mission of shedding a fixed amount of utility load but minimizing the amount of overall system transformer life lost.

Referring now to the drawings, FIGS. 1-4 are flow diagrams illustrating methods of providing transformer rating information in accordance with various exemplary embodiments of the present invention. As will be appreciated by those skilled in the art, in each of the drawings certain steps may be added or removed, and the order of certain of the steps may be rearranged, within the scope of the present invention.

Referring specifically to FIG. 1, k-factors for eddy losses and stray losses of a transformer are determined at step 100. As will be appreciated by those skilled in the art, a k-factor is a quantification of harmonic content. Such k-factors (Ke and Ks, that is, k-factors for eddy and stray losses, respectively) may be calculated using one or more industry standard formulas (e.g., ANSI, IEEE, IEC, etc.). At step 102, a distribution of transformer losses is determined. Although step 102 references only eddy losses and stray losses, other transformer losses (e.g., no load losses, resistive losses, etc.) may also be determined as a percentage of total transformer losses. The k-factors determined at step 100 (and in certain embodiments of the present invention the distribution determined at step 102) are used in step 104 to provide a revised transformer rating.

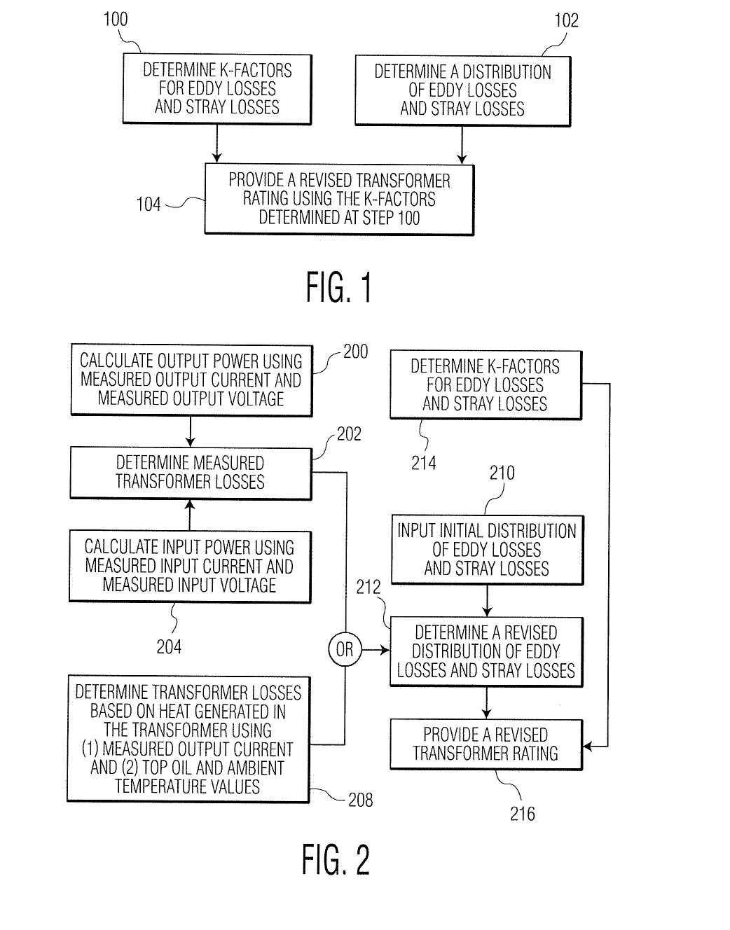

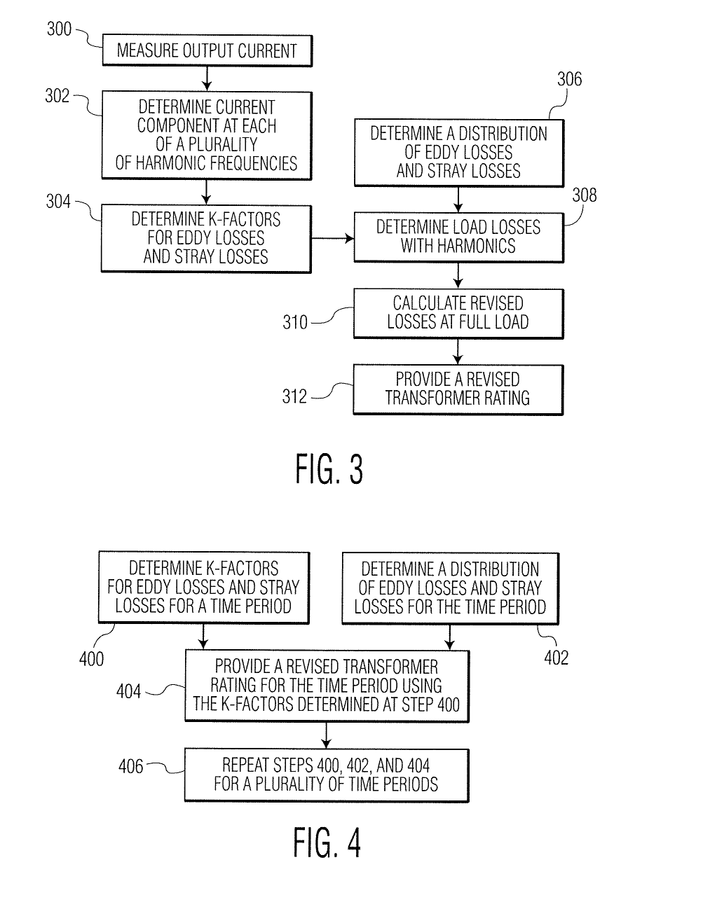

Each of the steps shown in FIG. 1 (and in FIG. 4) may be accomplished in a number of ways. Partial exemplary techniques for these steps are shown in FIGS. 2-3. More specifically, FIG. 2 illustrates certain exemplary techniques which may be used in step 102 of FIG. 1. As will be appreciated by those skilled in the art, transformer losses include various types of losses (e.g., core losses/no load losses, resistive losses, stray losses, and eddy losses). Although certain types of losses may be accurately estimated/calculated, stray losses and eddy losses are more difficult to determine. The technique illustrated in FIG. 2 may be used to more accurately estimate the stray losses and eddy losses as a percentage of the total transformer losses. At step 210, an initial distribution of eddy losses and stray losses are input to step 212. This initial distribution (e.g., what percentage of the total losses are eddy losses and what percentage of the total losses are stray losses) may be estimated, guessed, or otherwise provided (e.g., manually input) by the user. Although step 210 references only eddy losses and stray losses, other transformer losses (e.g., no load losses, resistive losses) may also be input.

Additional information is also provided to step 212: in the example shown in FIG. 2, information related to transformer losses is provided by at least one of two techniques shown in FIG. 2. At step 200, transformer output power is calculated using measured output transformer current and measured output transformer voltage. At step 204, transformer input power is calculated using measured input transformer current and measured input transformer voltage. The difference between the transformer input power from step 204, and the transformer output power at step 200, is used to determine the measured transformer losses at step 202. At step 208, transformer losses are determined using a measured output transformer current as well as top oil and ambient temperatures. Thus, transformer losses are provided at steps 202 and 208—and one or more of these is provided to step 212 (along with the initial distribution of transformer losses from step 210) to determine a revised distribution of eddy losses and stray losses (where the distribution of losses may also relate to other transformer losses such as no load losses, resistive losses, etc.).

As will be appreciated by those skilled in the art, the determination at step 212 may be accomplished in a number of ways. For example, the process of determining the revised distribution at step 212 may be an iterative process repeated until (1) a transformer loss value calculated using the revised distribution is substantially equivalent to (2) a transformer loss value measured including the harmonic content. The final (e.g., final in the sense of the final value of an iterative or closed loop process) revised distribution from step 212 is provided to step 216, along with the k-factors determined at step 214, in order to provide a revised transformer rating at step 216. As will be appreciated by those skilled in the art, step 212 is analogous to step 102 of FIG. 1, step 214 is analogous to step 100 of FIG. 1, and step 216 is analogous to step 104 of FIG. 1.

In a more specific example, the determination made at step 212 may involve solving a system of two equations and two unknowns (i.e., where the two unknowns are the eddy losses and stray losses of the transformer at a given KVA rating). For example, two exemplary expressions are provided below:
Total Transformer Losses (measured at a given KVA with a first level of harmonics)=Core Losses+Resistive Winding Losses+Ke*(eddy losses)+Ks*(stray losses); and
(2) Total Transformer Losses (measured at the given KVA without harmonics, or at a second level of harmonics different from the first level of equation (1))=Core Losses+Resistive Winding Losses+Ke*(eddy losses)+Ks*(stray losses), where Ke=Ks=1 for a no harmonics condition.

As will be appreciated by those skilled in the art, the Total Transformer Losses for each of equation (1) and (2) are measurable quantities (e.g., see steps 200-204 and 208 of FIG. 2). Further, the Core Losses and the Resistive Winding Losses are either known or may be closely approximated at a given KVA value (e.g., using a transformer test report) and do not vary with a change in harmonic content. Thus, it can be seen that, if the harmonics vary at a given KVA value, it would be possible to calculate the value of eddy losses and stray losses. Through continued recalculation, it is possible to improve upon the calculation of eddy losses and stray losses at a given load. Further, it is also possible to improve upon the calculation of Ke and Ks themselves. In any event, as will be appreciated by those skilled in the art, the manner of determination of the distribution of eddy losses and stray losses may vary.

In FIG. 3, steps 300-304 correspond to step 100 of FIG. 1, step 306 corresponds to step 102 of FIG. 1, and steps 308-312 correspond to step 104 of FIG. 1. At step 300, an output current of the transformer is measured. At step 302, the output current measured at step 300 is used to determine a current component at each of a plurality of harmonic frequencies (e.g., integer multiples of a fundamental frequency, where the fundamental frequency may be 50 Hz, 60 Hz, or other fundamental frequencies). The current components determined at step 302 are used (e.g., in connection with an industry standard formula) at step 304 to determine k-factors for the eddy losses and the stray losses. These k-factors from step 304, as well as the distribution of eddy losses and stray losses from step 306 (where the distribution of losses may also relate to other transformer losses such as no load losses, resistive losses, etc.), are provided to step 308. At step 308, load losses with harmonics are determined. At step 310, revised losses at full load are calculated. For example, the calculation of the losses may include per-unit resistive losses, Ke* per-unit eddy losses, and Ks* per-unit stray losses. At step 312, the revised transformer rating is provided. For example, the revised transformer rating may be the nameplate rating de-rated by a factor. In one specific example, the nameplate rating may be adjusted wherein the new load rating has the same total losses (including losses as a result of harmonics) that the transformer would have at full load (without harmonic losses).

As will be appreciated by those skilled in the art, the revised transformer ratings may be calculated based on information from a given time period (e.g., a 5 minute time period, a 15 minute time period, etc.). Further, the transformer may be updated at a given time interval (a 5 minute time interval, a 15 minute time interval, etc.). FIG. 4 illustrates such an implementation. K-factors for eddy losses and stray losses of a transformer for a time period (e.g., a 15 minute time period) are determined at step 400. At step 402, a distribution of eddy losses and stray losses for the time period is determined (where the distribution of losses may also relate to other transformer losses such as no load losses, resistive losses, etc.). The k-factors determined at step 400 (and in certain embodiments of the present invention the distribution determined at step 402) are used in step 404 to provide a revised transformer rating for the time period. At step 406, each of steps 400, 402, and 404 are repeated for a plurality of successive time periods. Thus, in such an implementation, the transformer rating is dynamically updated based on the harmonic current seen at each of the time periods.

The present invention may also be implemented as a system for providing transformer rating information. Such a system may include monitoring equipment for obtaining data related to the transformer (e.g., input voltage measurements to the transformer, input current measurements to the transformer, output voltage measurements from the transformer, output current measurements from the transformer, oil temperature values, ambient temperature values, etc.). Exemplary monitoring equipment may be, for example, a TransformerIQ™ product marketed by Gridsense, Inc. of West Sacramento, Calif. The system may also include a computer for providing revised ratings for the transformer using k-factors for eddy losses and stray losses related to the transformer (e.g., k-factors for a predetermined time period). The computer (e.g., including computer program instructions) may also be used in connection with other operations described above in connection with the present invention.

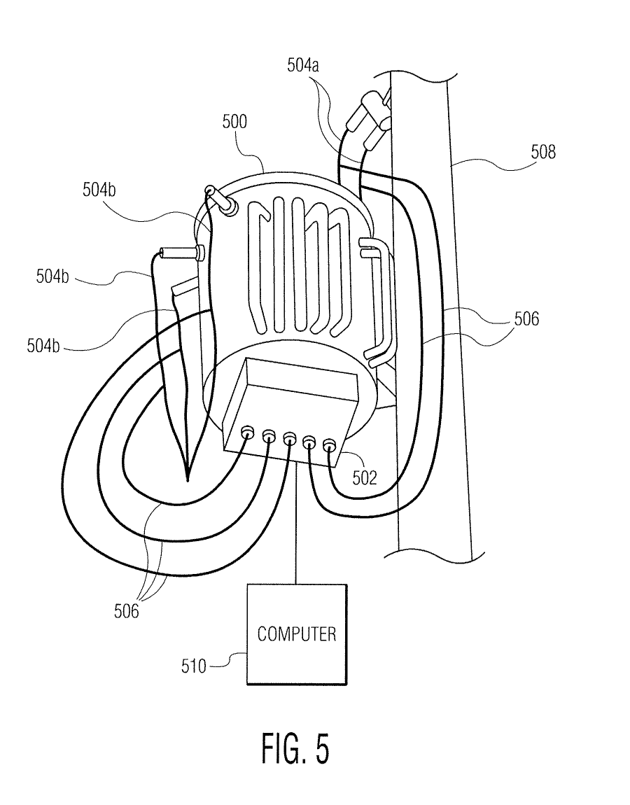

The present invention has particular application in connection with distribution transformers (e.g., pole-mounted transformers, residential transformers, etc.). In one example, the present invention has particular application for transformers having a KVA rating of between 15-500 KVA. FIG. 5 illustrates a pole-mounted transformer 500 mounted to a pole 508. FIG. 5 also illustrates primary leads 504a and secondary leads 504b. Monitoring equipment 502 is provided local to transformer 500 (in FIG. 5 monitoring equipment 502 is attached to transformer 500). Leads 506 are used to bring data (e.g., current data, voltage data, etc.) related to transformer 500 to monitoring equipment 502. Although illustrated in FIG. 5 as direct connections (e.g., a direct connection between a primary lead 504a and a lead 506), it is understood that such connections may be indirect connections (e.g., through a current transformer). It is also understood that different or additional inputs (e.g., top oil temperature data, ambient temperature data, etc.) may be provided to monitoring equipment 502. As will be appreciated by those skilled in the art, data from monitoring equipment 502 may be provided to a computer 510 to provide the revised rating for transformer 500. Further, monitoring equipment 502 may also be considered to include computer 510 (e.g., internal to monitoring equipment 502, in contrast to the illustration in FIG. 5) for providing the revised rating for transformer 500.

In one implementation it is considered that the revised transformer load rating will result in substantially the same loss of life that the transformer would see at a normal full load without harmonic content. However, the revised transformer load rating is not so limited.

The present invention has primarily been described in connection with re-rating (i.e., providing a revised rating) the transformer in connection with the continuous rating of the transformer (e.g., the power rating at which the transformer can continuously operate without exceeding the rated temperature). However, the methods and systems described herein may also be used for alternate implementations. For example, the re-rating provided in connection with the present invention can also be used to provide a revised power/load rating at which the transformer can operate for a shorter period of time (e.g., 30 minutes, 60 minutes, etc.) without exceeding a prescribed temperature. For example, a user of a transformer may provide some input data such as a desired power/load rating, a desired time to operate, and/or a desired temperature. The systems and methods described herein (taking into account the harmonic content) may then be used to provide the user with output data such as a power/load rating, a time to operate, and/or a temperature. In one specific example, a user may provide the desired load rating, and the systems and methods described herein may be used to provide the time at which the transformer may be operated at that desired load rating. In another specific example, a user may provide the desired time period to operate, and the systems and methods described herein may be used to provide the load at which the transformer may be operated for that desired time period.

Although illustrated and described above with reference to certain specific embodiments, the present invention is nevertheless not intended to be limited to the details shown. Rather, various modifications may be made in the details within the scope and range of equivalents of the claims and without departing from the spirit of the invention.

What is claimed:

1. A method of providing transformer rating information, the method comprising the steps of:
(a) determining k-factors for eddy losses and stray losses related to a transformer; and
(b) providing a revised rating for the transformer using the k-factors determined at step (a).

2. The method of claim 1 further comprising the step of (c) determining a distribution of eddy losses and stray losses for the transformer, wherein the distribution is used in connection with providing the revised rating of step (b).

3. The method of claim 2 wherein step (c) includes (c1) providing an initial distribution of eddy losses and stray losses for the transformer, (c2) calculating a total power output of the transformer with the initial distribution of eddy losses and stray losses, and (c3) adjusting a distribution of eddy losses and stray losses until the calculated total power output is substantially equivalent to a measured total power output of the transformer.

4. The method of claim 2 wherein losses of the transformer are measured, the measured losses being used in step (c).

5. The method of claim 4 wherein the losses of the transformer are measured using measurements of output current, output voltage, input current, and input voltage of the transformer.

6. The method of claim 4 wherein the losses of the transformer are measured by calculating a difference between an input power to the transformer and an output power from the transformer.

7. The method of claim 4 wherein the losses of the transformer are measured using measurements of at least one of an output current of the transformer, a top oil temperature of the transformer, and an ambient temperature value local to the transformer.

8. The method of claim 1 wherein step (a) includes measuring an output current of the transformer, and determining components of the output current at each of a plurality of harmonic frequencies.

9. The method of claim 1 wherein in step (b) the revised rating is determined to be a load rating having a transformer loss value including harmonic losses that is equivalent to a loss value without harmonic losses at a nameplate load rating.

10. The method of claim 1 wherein each of steps (a) and (b) are repeated for a plurality of time periods.

11. The method of claim 1 wherein step (b) includes providing the revised rating substantially dynamically.

12. The method of claim 1 wherein step (b) includes providing the revised rating substantially dynamically at a predetermined time interval.

13. The method of claim 1 wherein the transformer is a pole-mounted distribution transformer.

14. The method of claim 1 wherein the transformer has a rating of between 15-500 KVA.

15. A method of providing transformer rating information, the method comprising the steps of:
(a) determining k-factors for eddy losses and stray losses related to a transformer for a time period; and
(b) providing a revised rating for the transformer for the time period using the k-factors determined at step (a); and
(c) repeating steps (a) and (b) for a plurality of additional time periods.

16. A system for providing transformer rating information, the system comprising:
monitoring equipment for obtaining data related to a transformer; and
a computer for providing a revised rating for the transformer using k-factors for eddy losses and stray losses related to the transformer.

17. The system of claim 16 wherein the computer uses a distribution of eddy losses and stray losses for the transformer to provide the revised rating.

18. The system of claim 16 wherein the monitoring equipment is installed local to the transformer.

19. The system of claim 16 wherein the data related to the transformer include at least one of input voltage measurements to the transformer, input current measurements to the transformer, output voltage measurements from the transformer, output current measurements from the transformer, oil temperature values from the transformer, and ambient temperature values local to the transformer.

20. The system of claim 16 wherein the data related to the transformer include each of input voltage measurements to the transformer, input current measurements to the transformer, output voltage measurements from the transformer, output current measurements from the transformer, oil temperature values from the transformer, and ambient temperature values local to the transformer.
